(19) United States
(12) Patent Application Publication
(10) Pub. No.: US 2024/0063219 A1
(43) Pub. Date: Feb. 22, 2024

(54) INTEGRATED DEPLETION AND ENHANCEMENT MODE GALLIUM NITRIDE HIGH-ELECTRON MOBILITY TRANSISTORS

(71) Applicant: GlobalFoundries U.S. Inc., Malta, NY (US)

(72) Inventors: Santosh Sharma, Austin, TX (US); Jerry Joseph James, Singapore (SG); Steven J. Bentley, Menands, NY (US); Francois Hebert, San Mateo, CA (US); Richard J. Rassel, Essex Junction, VT (US)

(21) Appl. No.: 17/819,980

(22) Filed: Aug. 16, 2022

(51) Int. Cl. H01L 27/088; H01L 29/66; H01L 29/778; H01L 29/40; H01L 29/06

(52) U.S. Cl. CPC H01L 27/0883; H01L 29/66462; H01L 29/7786; H01L 29/401; H01L 29/402; H01L 29/0607

(57) ABSTRACT

A structure for an III-V integrated circuit includes an integrated depletion and enhancement mode gallium nitride high electron mobility transistors (HEMTs). The structure includes a first, depletion mode HEMT having a first source, a first drain and a first fieldplate gate between the first source and the first drain, and a second, enhancement mode HEMT having a second source and a second drain. The second HEMT also includes a gallium nitride (GaN) gate and a second fieldplate gate between the second source and the second drain. The second fieldplate gate of the second HEMT may be closer to the second drain than the GaN gate. The structure provides a reliable, low leakage, high voltage depletion mode HEMT (e.g., with operating voltages of greater than 100V, but with a pinch-off voltage of less than 6 Volts) integrated with a gallium nitride (GaN) gate-based enhancement mode HEMT.

### BACKGROUND

The present disclosure relates to transistors and, more particularly, to embodiments of a structure including integrated depletion and enhancement mode gallium nitride high electron mobility transistors (HEMTs).

III-V semiconductor devices, such as high electron mobility transistors (HEMTs) and metal-insulator-semiconductor HEMTs (MISHEMTs), have emerged as a leading technology for power switching, radio frequency (RF) and millimeter wave (mmWave) (e.g., 3-300 GHz) wireless applications. Integration of depletion mode and enhancement mode HEMTs and MISHEMTs can be challenging. For example, a reliable low leakage, high voltage depletion mode device with a low pinch-off (<6V) integrated with a p-type gallium nitride (pGaN) gate-based enhancement mode HEMT is not currently available.

### SUMMARY

All aspects, examples and features mentioned below can be combined in any technically possible way.

An aspect of the disclosure provides a structure for an III-V integrated circuit, comprising: a first transistor having a first source, a first drain and a first fieldplate gate between the first source and the first drain; and a second transistor having a second source and a second drain, the second transistor including a gallium nitride (GaN) gate and a second fieldplate gate between the second source and the second drain, the second fieldplate gate between the second drain and the GaN gate.

Another aspect of the disclosure includes any of the preceding aspects, and the fieldplate gates have a same composition, the composition being different than a composition of the GaN gate.

Another aspect of the disclosure includes any of the preceding aspects, and further comprising a first interconnect coupling the second fieldplate gate and the second source.

Another aspect of the disclosure includes any of the preceding aspects, and further comprising an interconnect coupling the first and second field plate gates.

Another aspect of the disclosure includes any of the preceding aspects, and each fieldplate gate includes a step.

Another aspect of the disclosure includes any of the preceding aspects, and the GaN gate includes a p-type GaN (pGaN) layer underneath a metallic layer.

Another aspect of the disclosure includes any of the preceding aspects, and the pGaN layer is in direct contact with the metallic layer.

Another aspect of the disclosure includes any of the preceding aspects, and further comprising an isolating doping region adjacent to at least one side of: the GaN gate, the first fieldplate gate and the second fieldplate gate.

Another aspect of the disclosure includes any of the preceding aspects, and the first transistor is configured to operate as a depletion mode device, and the second transistor is configured to operate as an enhancement mode device.

Another aspect of the disclosure includes any of the preceding aspects, and each transistor includes a passivation layer over an aluminum gallium nitride (AlGaN) barrier layer, and wherein the first fieldplate gate includes a first portion extending into a first recess defined in the AlGaN barrier layer and the second fieldplate gate includes a second portion extending into a second recess defined in the AlGaN barrier layer.

An aspect of the disclosure includes a structure for an III-V integrated circuit, comprising: a depletion mode high electron mobility transistor (DM HEMT) having a first source, a first drain and a first fieldplate gate between the first source and the first drain; and an enhancement mode HEMT (EM HEMT) having a second source and a second drain, and the EM HEMT having a gallium nitride (GaN) gate and a second fieldplate gate between the second source and the second drain, wherein the second fieldplate gate is closer to the second drain than the GaN gate.

Another aspect of the disclosure includes any of the preceding aspects, and the first and second fieldplate gates have a same composition, the composition being different than a composition of the GaN gate.

Another aspect of the disclosure includes any of the preceding aspects, and further comprising a first interconnect coupling the second fieldplate gate and the second source.

Another aspect of the disclosure includes any of the preceding aspects, and each fieldplate gate includes a step.

Another aspect of the disclosure includes any of the preceding aspects, and the GaN gate includes a p-type GaN (pGaN) layer underneath a metallic layer.

Another aspect of the disclosure includes any of the preceding aspects, and the pGaN layer is in direct contact with the metallic layer.

Another aspect of the disclosure includes any of the preceding aspects, and each HEMT includes a passivation layer over an aluminum gallium nitride (AlGaN) barrier layer, and wherein the first fieldplate gate includes a first portion extending into a first recess defined in the AlGaN barrier layer and the second fieldplate gate includes a second portion extending into a second recess defined in the AlGaN barrier layer.

An aspect of the disclosure relates to a method, comprising: forming a p-type gallium nitride (pGaN) gate in an enhancement mode high electron mobility transistor (EM HEMT) region over an aluminum gallium nitride (AlGaN) barrier layer over a gallium nitride (GaN) layer over a substrate; forming a passivation layer over the pGaN gate in the EM HEMT region and a depletion mode high electron mobility transistor (DM HEMT) region over the AlGaN layer and the GaN layer; forming a first fieldplate gate over the passivation layer and adjacent the pGaN gate in the EM HEMT region and a second fieldplate gate over the passivation layer in the DM HEMT region; forming a first source and a first drain on opposing sides of the first fieldplate gate; and forming a second source and a second drain on opposing sides the pGaN gate and the second fieldplate gate, the second fieldplate gate closer to the second drain than the pGaN gate, wherein each fieldplate gate includes a step.

Another aspect of the disclosure includes any of the preceding aspects, and the first and second fieldplate gates have a same composition, the composition being different than a composition of the pGaN gate.

Another aspect of the disclosure includes any of the preceding aspects, and the first fieldplate gate includes a first portion extending into a first recess defined in the passivation layer and the AlGaN layer, and the second fieldplate gate includes a second portion extending into a second recess defined in the passivation layer and the AlGaN layer.

Two or more aspects described in this disclosure, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1 shows a cross-sectional view of a structure, according to embodiments of the disclosure.

FIG. 2 shows a cross-sectional view of a structure, according to embodiments of the disclosure.

FIG. 3 shows a cross-sectional view of a structure, according to embodiments of the disclosure.

FIG. 4 shows a cross-sectional view of a structure, according to embodiments of the disclosure.

FIGS. 5A-B, 6A-B, 7A-B show cross-sectional views of a method of forming the structure, according to embodiments of the disclosure.

FIG. 8 shows a cross-sectional view of a structure, according to embodiments of the disclosure.

FIG. 9 shows a cross-sectional view of a structure, according to embodiments of the disclosure.

FIG. 10 shows a cross-sectional view of a structure, according to embodiments of the disclosure.

FIG. 11 shows a cross-sectional view of a structure, according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (a) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

Embodiments of the disclosure include a structure for an III-V integrated circuit including integrated depletion mode and enhancement mode gallium nitride high electron mobility transistors (HEMTs). More particularly, embodiments of the disclosure include a first, depletion mode HEMT having a first source, a first drain and a first fieldplate gate between the first source and the first drain, and a second, enhancement mode HEMT having a second source and a second drain. The second HEMT also includes a gallium nitride (GaN) gate and a second fieldplate gate between the second source and the second drain. The second fieldplate gate of the second HEMT is between the second drain than the GaN gate. The structure provides a reliable, low leakage, high voltage depletion mode HEMT (e.g., with operating voltages of greater than 100V, but with a pinch-off voltage of less than 6 Volts) integrated with a gallium nitride (GaN) gate-based enhancement mode HEMT.

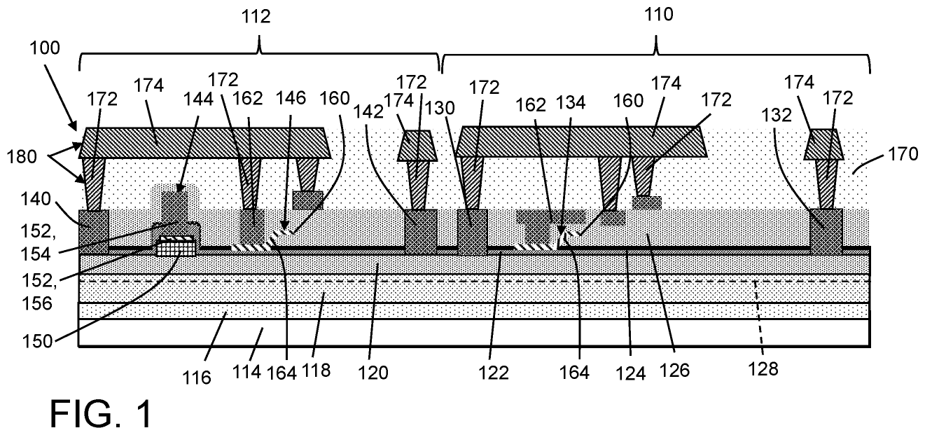

FIG. 1 shows a cross-sectional view of a structure 100 for an III-V integrated circuit. Structure 100 includes a first transistor 110 and a second transistor 112. Transistors 110, 112 can be above multiple epitaxially grown semiconductor layers on a semiconductor substrate 114. Semiconductor substrate 114 can be, for example, a silicon or silicon-based substrate (e.g., a silicon carbide (SiC) substrate), a sapphire substrate, a III-V semiconductor substrate (e.g., a gallium nitride (GaN) substrate or some other suitable III-V semiconductor substrate), a silicon substrate (perhaps doped p-type), or any other suitable substrate for a III-V semiconductor device. Epitaxially grown semiconductor layers on substrate 114 can include, for example: an optional buffer layer 116 on the top surface of semiconductor substrate 114; a channel layer 118 on buffer layer 116; and a barrier layer 120 on channel layer 118. These epitaxial grown semiconductor layers can be, for example, III-V semiconductor layers. Those skilled in the art will recognize that a III-V semiconductor refers to a compound obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP).

Optional buffer layer 116 can be employed to facilitate growth of channel layer 118 and to provide for lattice constants of substrate 114 below and channel layer 118 above. Buffer layer 116 can be doped or undoped. Optionally, buffer layer 116 can be carbon-doped. Barrier layer 120 can have a band gap that is wider than the bandgap of channel layer 118 for the device channel. Those skilled in the art will recognize that the barrier and channel materials can be selected so that a heterojunction is formed at the interface between the two layers, thereby resulting in the formation of a two-dimensional electron gas (2DEG) region 128 in channel layer 118 (see dashed box). This 2DEG region 128 in channel layer 118 can provide the conductive pathway for the drifting of charges between the source and the drain.

In some embodiments, buffer layer 116 could be a carbon-doped gallium nitride (C-GaN) buffer layer or a buffer layer of any other material suitable for use as a buffer layer of a HEMT or MISHEMT. Channel layer 118 could be a gallium nitride (GaN) layer or a III-V semiconductor channel layer made of any other III-V semiconductor compound suitable for use as a channel layer in a HEMT or MISHEMT. Hence, channel layer 118 may also be referenced as a “GaN channel layer” herein. Barrier layer 120 could be an aluminum gallium nitride (AlGaN) barrier layer or a barrier layer of any other material suitable for use as a barrier layer in a HEMT or MISHEMT. Hence, barrier layer 120 may also be referenced as an “AlGaN barrier layer” herein. For purposes of illustration, the figures and the description depict the epitaxially grown layers (e.g., buffer layer 116; channel layer 118; and barrier layer 120) as being single layered structures (i.e., comprising one layer of buffer material, one layer of channel material and one layer of barrier material). However, it should be understood that, alternatively, any one or more of the epitaxially grown layers could be multi-layered structures (e.g., comprising multiple sub-layers of different buffer materials, multiple sub-layers of different III-V semiconductor channel materials and/or multiple sub-layers of different barrier materials).

One or more passivation layers may be over barrier layer 120. In the example shown, two passivation layers 122, 126 are shown with an etch stop layer 124 therebetween. Passivation layers 122, 126 may include one or more layers of any appropriate passivation material such as but not limited to aluminum oxide (Al₂O₃), silicon nitride (Si₃N₄) and/or silicon oxide (SiOₓ). For purposes of illustration, the figures and the description depict passivation layers 122, 126 as being single layered structures. However, it should be understood that, alternatively, one or both passivation layers 122, 126 could be multi-layered structures, e.g., comprising multiple sub-layers of different passivation materials. Etch stop layer 124 may be provided between passivation layers 122, 126 to protect the lower passivation layer 122 during etching processes. Etch stop layer 124 may include any now known or later developed etch stop material such as silicon nitride.

First transistor 110 is illustrated as a depletion mode HEMT (hereinafter “DM HEMT 110”) and second transistor 112 is illustrated as an enhancement mode HEMT (hereinafter “EM HEMT 112”). “Depletion mode” indicates DM HEMT 110 is typically in an on-state and requires a negative voltage (referred to as a “pinch-off voltage”) to be applied to a gate thereof to turn it off, i.e., to deplete electron flow through 2DEG region 128 in channel layer 118. “Enhancement mode” indicates EM HEMT 112 is typically in an off-state and requires a positive voltage (referred to as a “threshold voltage”) to be applied to a gate thereof to turn it on, i.e., enhance/allow electron flow through 2DEG region 128 and channel layer 118.

DM HEMT 110 includes a first source 130, a first drain 132 and a first fieldplate gate 134 between first source 130 and first drain 132. EM HEMT 112 has a second source 140 and a second drain 142. In addition, EM HEMT 112 includes a gallium nitride (GaN) gate 144 and a second fieldplate gate 146 between second source 140 and second drain 142. That is, GaN gate 144 and second fieldplate gate 146 are both between second source 140 and second drain 142. As shown, second fieldplate gate 146 is closer to second drain 142 than GaN gate 144. GaN gate 144 may include a p-type GaN (pGaN) layer 150 underneath a metallic layer 152. Hence, GaN gate 144 may also be referenced herein as a “pGaN gate.” In certain embodiments, pGaN layer 150 is in direct contact with metallic layer 152, i.e., there are no intervening layers. Metallic layer 152 may include, for example, a metal or metal alloy 154 such as but not limited to titanium aluminum or titanium nitride, and an ohmic contact 156 such as titanium nitride (TiN) or any other appropriate ohmic contact material. pGaN layer 152 may include, for example, p-type doped gallium nitride. The p-type dopant may include any appropriate p-type dopant for GaN such as but not limited to magnesium, zinc, cadmium and carbon. Source regions 130, 140 and drain regions 132, 142 may each include a metal or metal alloy such as but not limited to titanium aluminum or titanium nitride.

Fieldplate gates 134, 146 have a same composition. The composition is different than a composition of GaN gate 144. More particularly, fieldplate gates 134, 146 each includes a fieldplate portion 160 and a conductor portion 162. Fieldplate portion 160 may include, for example, titanium nitride, and conductor portion 162 may include, for example, titanium nitride or titanium aluminum. Each fieldplate gate 134, 146 includes a step 164 therein, i.e., in fieldplate portion 160 thereof. Steps 164 act to provide field shaping to reduce the impact of sharp corners/edges that can result in a strong electric field that can change functions of the devices. For example, sharp corners/edges of pGaN gate 144 can provide a strong electric field that can change functions of EM HEMT 112 over time, e.g., change a threshold voltage and/or saturation currents. Fieldplate gates 146 forms a metal-insulator-semiconductor (MIS) capacitor that reduces field crowding at an edge of pGaN gate 144. Fieldplate gate 146 also supports using high voltage without using extensive amounts of GaN, which can be expensive. The same MIS capacitor structure used for fieldplate gate 146 in EM HEMT 112 is used for fieldplate gate 134 of DM HEMT 110. Fieldplate gate 134 is closer to 2DEG region 128 than other HEMT devices, which lowers a pinch-off voltage for DM HEMT 110, e.g., less than 6 V, but still allows it to operate at high voltage, e.g., greater than 100 V.

Structure 100 may include a variety of interconnects depending on the application thereof. Interconnects can be provided in any middle-of-line and/or back-end-of-line interlayer dielectric (ILD) layers 170 using known techniques. While one ILD layer 170 is shown, it will be recognized by those with skill in the art that more than one ILD layer may be provided. Interconnects may include any required contacts or vias (collectively “contacts” hereafter) 172 and metal wires 174. Each contact 172 may include any currently known or later developed conductive material configured for use in an electrical contact, e.g., tungsten (W). Contacts 172 may additionally include refractory metal liners (not shown) positioned alongside ILD layer 170 to prevent electromigration degradation, shorting to other components, etc. Additionally, selected portions of active semiconductor materials may include silicide regions (i.e., portions of semiconductor that are annealed in the presence of an overlying conductor to increase the electrical conductivity of semiconductor regions) to increase the electrical conductivity at their physical interface with contact(s) 172 where applicable. Metal wires 174 may include any appropriate conductors such as aluminum or copper. Metal wires 174 may also include refractory metal liners (not shown) positioned alongside ILD layer 170 to prevent electromigration degradation, shorting to other components, etc. In the FIG. 1 embodiment, structure 100 includes an interconnect 180 coupling second fieldplate gate 146 and second source 130.

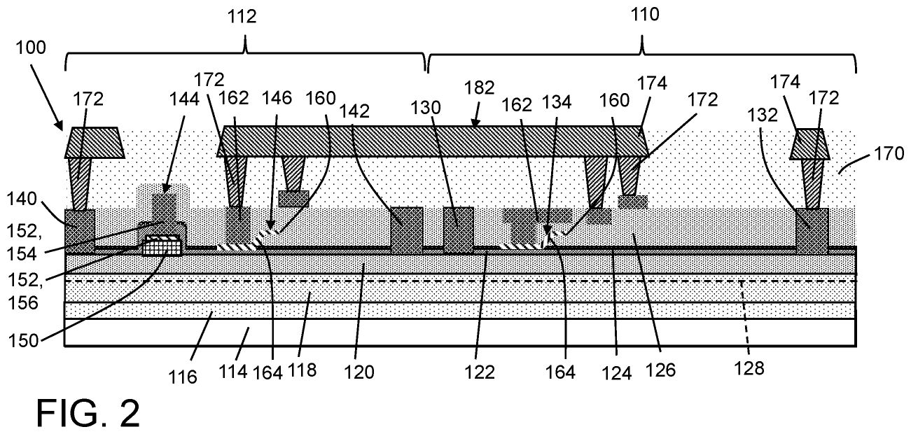

FIG. 2 shows a cross-sectional view of another embodiment of structure 100. In FIG. 2, structure 100 may include an interconnect 182 coupling first and second field plate gates 134, 146. (Contacts to certain structures, e.g., first source 130, second drain 142 omitted for clarity).

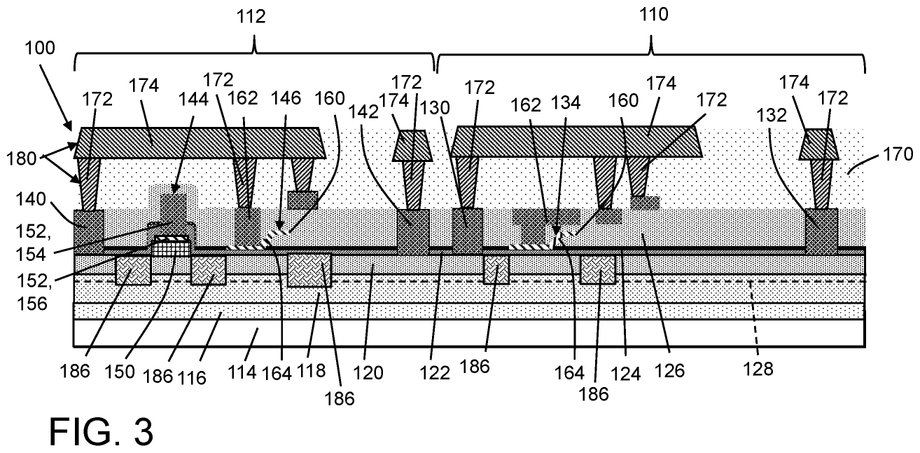

FIG. 3 shows a cross-sectional view of another embodiment of structure 100. In FIG. 3, structure 100 may include one or more isolating doping regions 186 (five shown) in one or more locations to isolated parts of structure 100. Isolating doping regions 186 may include any dopant capable of causing an electrical break in 2DEG region 128. For example, the dopants may include nitrogen and/or argon. An isolating doping region 186 may be adjacent to at least one side of: pGaN gate 144, first fieldplate gate 134 and second fieldplate gate 146. Isolation doping regions 186 may be doped in any manner, e.g., ion implanting using gates 134, 144, 146 to guide the implantation. While use of isolation doping regions 186 is shown with the FIG. 1 embodiment, it will be recognized that they are applicable to any embodiment described herein. While isolation regions 186 are shown to the side of each side pGaN gate 144, first fieldplate gate 134 and second fieldplate gate 146, any one or more of them may be omitted.

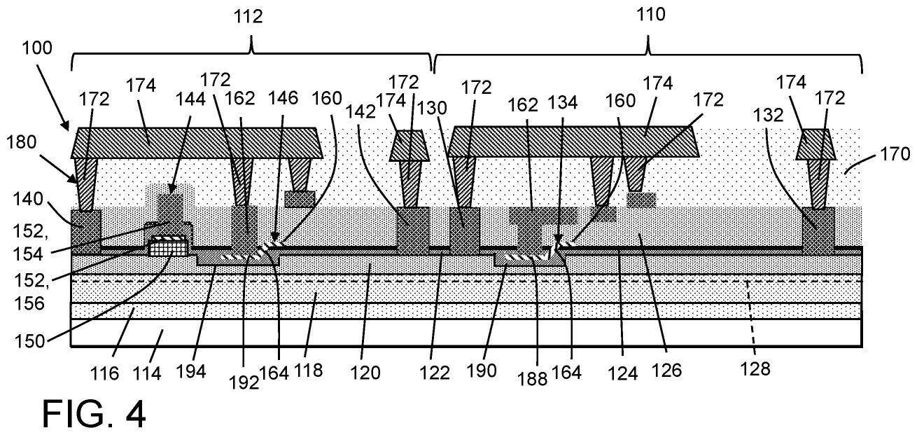

FIG. 4 shows a cross-sectional view of another embodiment of structure 100. In most cases, the closer fieldplates 134, 146 are to 2DEG region 128, the better the performance of transistors 110, 112. In FIG. 4, each transistor 110, 112 includes passivation layer 122 (and perhaps layer(s) 126) over AlGaN barrier layer 120. In this setting, first fieldplate gate 134 includes a first portion 188 (e.g., lower portion of fieldplate portion 160 and perhaps part of step 164) extending into a first recess 190 defined in AlGaN barrier layer 120 and second fieldplate gate 146 includes a second portion 192 (e.g., lower portion of fieldplate portion 160 and perhaps part of step 164) extending into a second recess 194 defined in AlGaN barrier layer 120. Passivation layer 122 separates fieldplate gates 134, 146 from AlGaN barrier layer 120 in a bottom of recesses 190, 194. As illustrated, in this manner, fieldplate gates 134, 146 are both closer to 2DEG region 128 than if just over passivation layer 122 (as in FIGS. 1-3), which reduces 2DEG region 128 concentration and lowers the necessary pinch-off voltage of DM HEMT 110. It also aids field crowding on pGaN gate 144 of EM HEMT 112. While recessing of AlGaN barrier layer 120 is shown for both fieldplates 134, 146, in an alternative embodiment, it may be provided for only one of them.

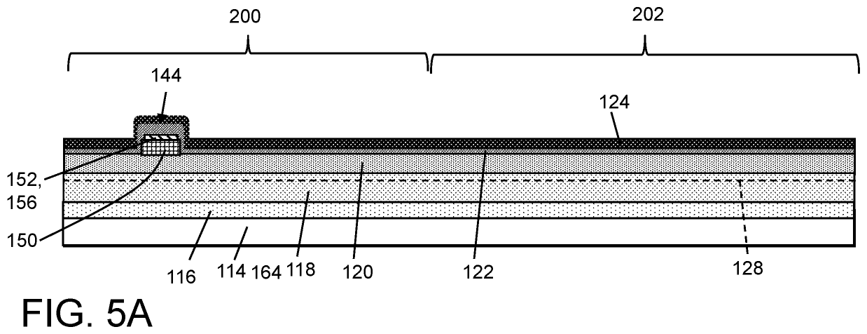

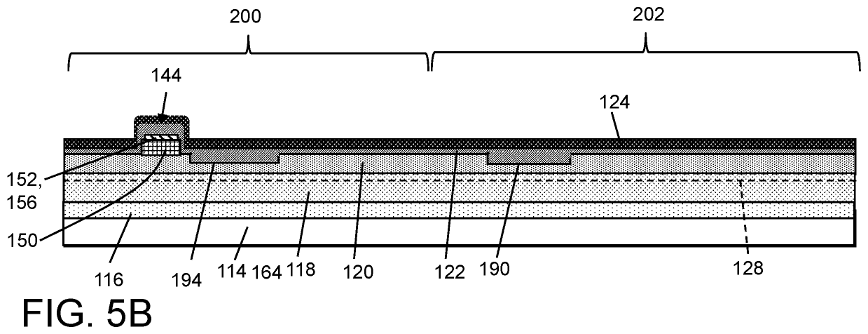

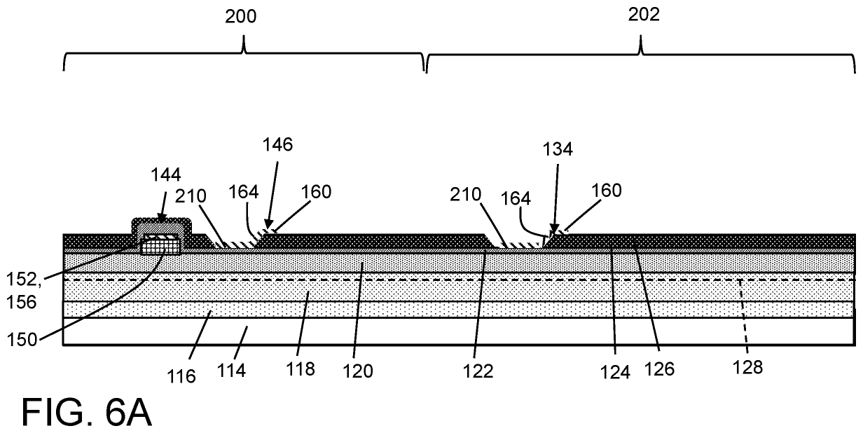

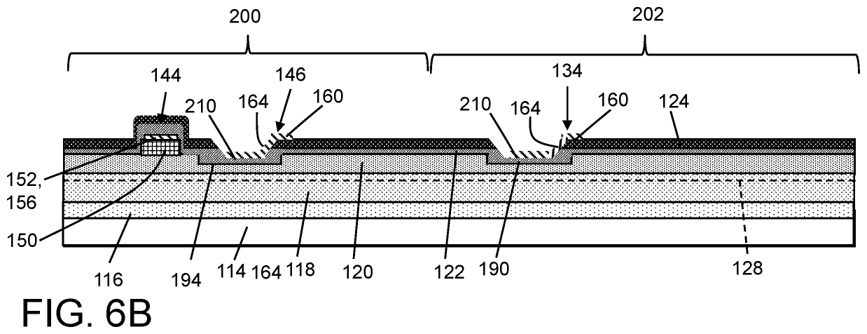

Turning to FIGS. 5A-B, 6A-B, 7A-B, cross-sectional views of embodiments of a method of forming structure 100 are illustrated. FIGS. 5A-B show forming p-type gallium nitride (pGaN) gate 144 in an enhancement mode high electron mobility transistor (EM HEMT) region 202 over AlGaN barrier layer 102 over GaN channel layer 118 over substrate 114. Optional buffer layer 116 is also shown but may not be necessary in all cases. Ohmic contact 156 of pGaN gate 144 (FIGS. 1-4) may also be formed at this stage. pGaN layer 150 and ohmic contact 156 may be formed using any now known or later developed semiconductor fabrication techniques. In one example, they may be formed by in-situ p-type doping (with, e.g., magnesium, cadmium, zinc or carbon) during epitaxial growth of GaN for form pGaN layer 150, followed by deposition of ohmic contact 156 material over pGaN layer 150 (e.g., titanium nitride using atomic layer deposition), and subsequent patterning using known photolithographic techniques. For example, a mask (not shown) may be formed over the layers in an area in which pGaN gate 144 is to exist, and an etch performed to remove the layers outside pGaN gate 144 (e.g., a reactive ion etch or other etch chemistry appropriate for GaN and/or titanium nitride). The mask may then be removed using any appropriate technique.

FIG. 5B shows an embodiment in which AlGaN barrier layer 120 has recesses 190, 194 defined therein. Recesses 190, 194 may be formed in AlGaN barrier layer 120 in any known or later developed fashion prior to formation of passivation layer 122 and etch stop layer 124, as described previously. For example, a mask (not shown) may be formed over AlGaN barrier layer 120, patterned to expose areas in which recesses 190, 194 are to exist, and an etch performed to remove the AlGaN material to form recesses 190, 194 (e.g., a reactive ion etch or other etch chemistry appropriate for barrier layer 120). The mask may then be removed.

FIGS. 5A-B also show forming passivation layer 122 over pGaN gate 144 in EM HEMT region 200 and in DM HEMT region 202 over AlGaN barrier layer 120 and GaN channel layer 118. Passivation layer 122 may be formed using any appropriate deposition technique such as atomic layer deposition (ALD). Etch stop layer 124 is also shown in this drawing. Etch stop layer 124, e.g., silicon nitride, 122 may be formed using any appropriate deposition technique such as atomic layer deposition (ALD). In the FIG. 5B embodiment, formation of passivation layer 122 may at least partially fill recesses 190, 194 (shown filled).

FIGS. 6A-B show cross-sectional views of forming a fieldplate gate 146 over passivation layer 122 and adjacent GaN gate 144, i.e., pGaN gate 144, in EM HEMT region 200 and forming a second fieldplate gate 134 over passivation layer 122 in DM HEMT region 202. FIG. 6A shows the process on the FIG. 5A embodiment, and FIG. 6B shows the process on the FIG. 5B embodiment. In any event, fieldplate gates 134, 146 may be formed simultaneously and of the same composition (materials). Fieldplate gates 134, 146 may be formed by forming recesses 210 in etch stop layer 124, e.g., using a patterned mask and etching into the layer, where the fieldplate gates are desired. In FIG. 6A, recesses 210 extend into etch stop layer 124 and perhaps part of passivation layer 124. In FIG. 6B, recesses 210 extend through etch stop layer 124 and part of passivation layer 122 within first recess 190 defined in AlGaN barrier layer 120 and second recess 194 defined in AlGaN barrier layer 120. Additional etching may be performed to round the corners of recesses 210, if necessary. The mask may then be removed. A layer of the metal or metal alloy, e.g., titanium nitride, of fieldplate gates 134, 146 may be deposited, e.g., using ALD or other appropriate deposition technique. The layer(s) extend over an edge of recesses 210 to form step 164 of each fieldplate gate 134, 146. The layer(s) may be patterned using another mask covering where fieldplate gates 134, 146 are to exist, and etching using an appropriate chemistry to remove excess material. As noted, fieldplate gates 134, 146 have a same composition. The composition is different than a composition of pGaN gate 144, i.e., it is not pGaN. Fieldplate gates 134, 146 each include fieldplate portion 160. Fieldplate portion 160 may include, for example, titanium nitride. Each fieldplate gate 134, 146 includes a step 164 therein, i.e., in fieldplate portion 160 thereof. Steps 164 act to provide, among other advantages, field shaping to reduce the impact of sharp corners/edges that can result in a strong electric field that can change functions of the devices.

FIGS. 7A-B show cross-sectional views of forming a first source 130 and a first drain 132 on opposing sides of first fieldplate gate 134 and forming a second source 140 and a second drain 142 on opposing sides pGaN gate 144 and second fieldplate gate 146. Second fieldplate gate 146 is closer to second drain 142 than pGaN gate 144. Source/drains 130, 132, 140, 142 may be formed at the same time as forming of conductor portions 162 that finalize fieldplate gates 134, 146, and finalize metallic layer 154 of pGaN gate 144. This process may include a Damascene process including depositing second passivation layer 126; patterning a mask (not shown) to expose areas of second passivation layer 126 in which the metal or metal alloy of the source/drains, metallic layer and conductor portions are desired; depositing the metal or metal alloy using any appropriate deposition technique; and planarizing. Any additional sections of metallic layer 154 and/or conductor portions 162 may be formed over lower portions thereof by repeating the Damascene process.

If desired, as shown in FIG. 3, isolating doping regions 186 may be formed at this stage. Isolation doping regions 186 may be doped in any manner, e.g., ion implanting using gates 134, 144, 146 to guide the implantation. Any dopant capable of causing an electrical break in 2DEG region 128 may be used, e.g., nitrogen and/or argon. An isolating doping region 186 may be adjacent to at least one side of: pGaN gate 144, first fieldplate gate 134 and second fieldplate gate 146. While isolation regions 186 are shown to the side of each side pGaN gate 144, first fieldplate gate 134 and second fieldplate gate 146, any one or more of them may be omitted.

Referring to FIGS. 1-4, interconnects can be formed using any now known or later developed semiconductor fabrication techniques. For example, depositing an ILD, patterning openings therein using a mask and etching, depositing metal layer(s) and planarizing. Interconnects can be provided in any middle-of-line and/or back-end-of-line interlayer dielectric (ILD) layers using known techniques. As noted, one or more ILD layers 170 may be used. Interconnects may include any required contacts or vias 172 and metal wires 174. Each contact 172 may include any currently known or later developed conductive material configured for use in an electrical contact, e.g., tungsten (W). Contacts 172 may additionally include refractory metal liners (not shown) positioned alongside ILD layer 170 to prevent electromigration degradation, shorting to other components, etc. Metal wires 174 may include any appropriate conductors such as aluminum or copper. Metal wires 174 may also include refractory metal liners (not shown) positioned alongside ILD layer 170 to prevent electromigration degradation, shorting to other components, etc. In the FIG. 1 embodiment, structure 100 includes an interconnect 180 coupling second fieldplate gate 146 and second source 130. In FIG. 2, structure 100 includes interconnect 182 coupling fieldplate gates 134, 146.

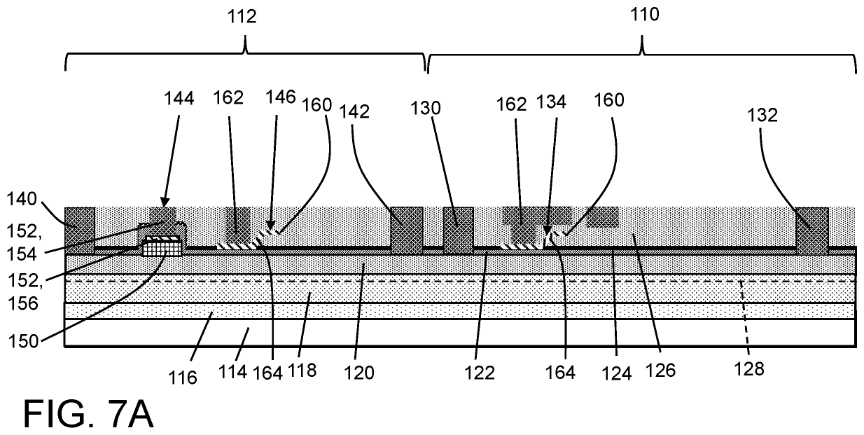

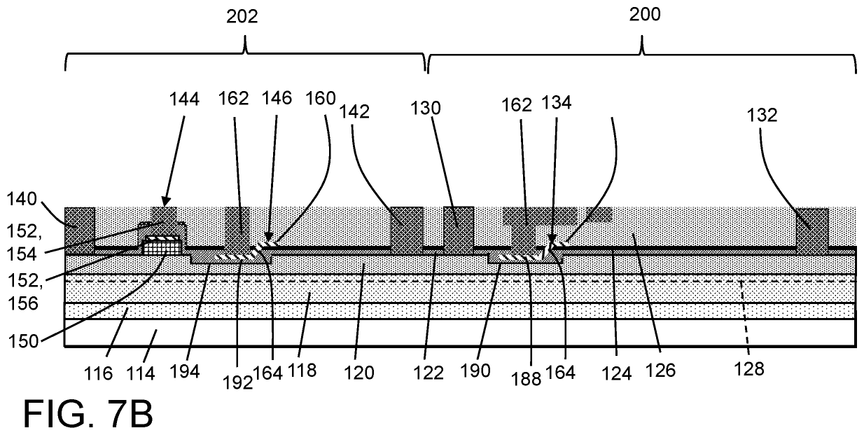

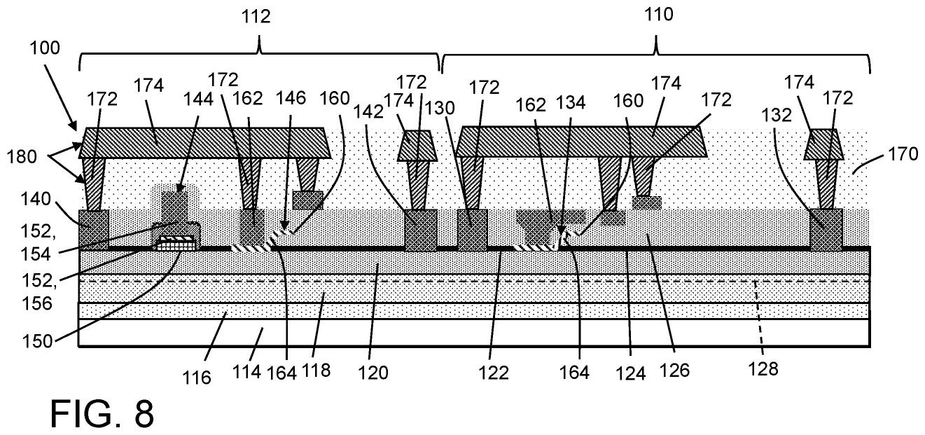

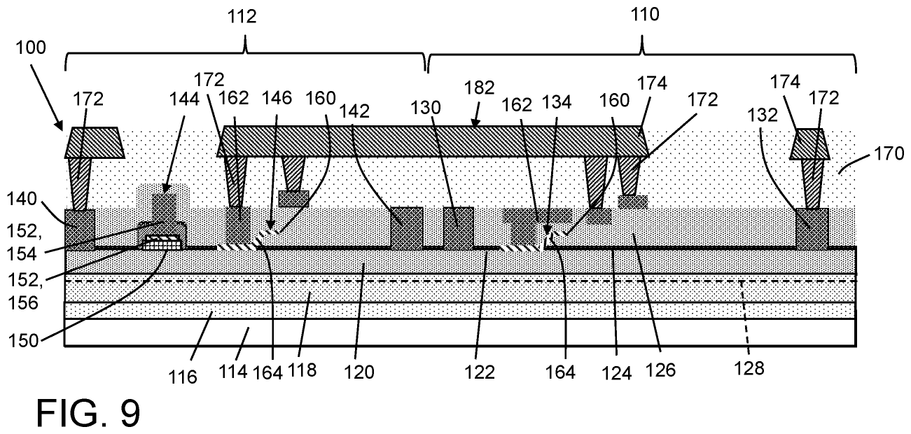

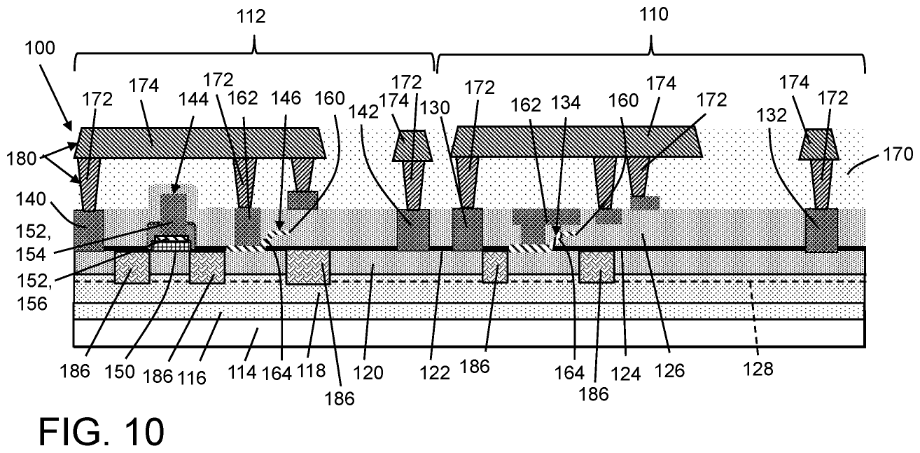

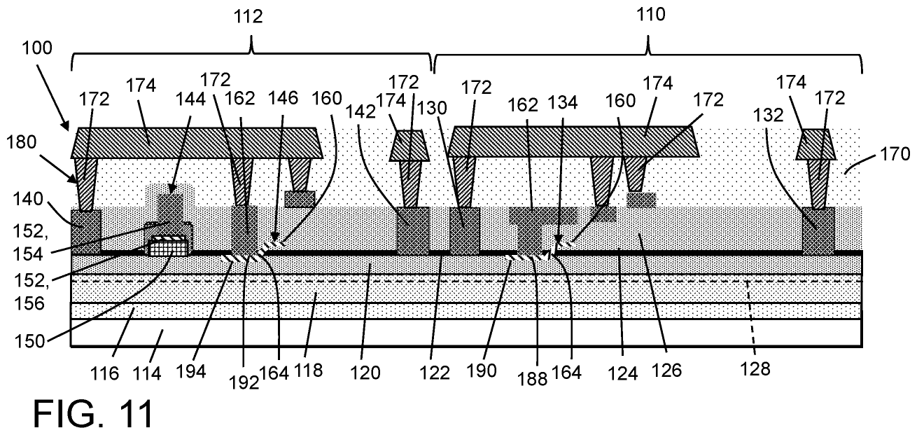

In the previous description, embodiments of the disclosure have been described with reference to a particular form of HEMT, i.e., a MISHEMT including metal-insulator-semiconductor (MIS) arrangement with passivation layer 122 acting as the insulator layer. FIGS. 8-11 show cross-sectional views of structure 100 as in FIGS. 1-4, according to alternative embodiments of the disclosure in which passivation layer 122 is omitted. FIGS. 8-11 are the same as the FIGS. 1-4 embodiments, respectively, but without passivation layer 122.

Embodiments of the disclosure provide various technical and commercial advantages, examples of which are discussed herein. Structure 100 employs a field plate gate 134 in DM HEMT 110 that is formed in the same process as fieldplate gate 146 in EM HEMT 112. First fieldplate gate 134 is closer to 2DEG region 128 at interface of barrier layer 120 and channel layer 118 than in current HEMTs, which lowers the pinch-off voltage of DM HEMT 110. DM HEMT 110 can have a pinch-off voltage of, e.g., less than 6 V, but still operate at greater than 100 V. In one example, operating voltages can be up to 1000 V. First fieldplate gate 134 also reduces current leakage and can shape fields in any manner necessary.

The method and structure as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate+/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure for an III-V integrated circuit, comprising:
a first transistor having a first source, a first drain and a first fieldplate gate between the first source and the first drain; and
a second transistor having a second source and a second drain, the second transistor including a gallium nitride (GaN) gate and a second fieldplate gate between the second source and the second drain, the second fieldplate gate between the second drain and the GaN gate.

2. The structure of claim 1, wherein the fieldplate gates have a same composition, the composition being different than a composition of the GaN gate.

3. The structure of claim 1, further comprising a first interconnect coupling the second fieldplate gate and the second source.

4. The structure of claim 1, further comprising an interconnect coupling the first and second field plate gates.

5. The structure of claim 1, wherein each fieldplate gate includes a step.

6. The structure of claim 1, wherein the GaN gate includes a p-type GaN (pGaN) layer underneath a metallic layer.

7. The structure of claim 6, wherein the pGaN layer is in direct contact with the metallic layer.

8. The structure of claim 1, further comprising an isolating doping region adjacent to at least one side of: the GaN gate, the first fieldplate gate and the second fieldplate gate.

9. The structure of claim 1, wherein the first transistor is configured to operate as a depletion mode device, and the second transistor is configured to operate as an enhancement mode device.

10. The structure of claim 1, wherein each transistor includes a passivation layer over an aluminum gallium nitride (AlGaN) layer, and wherein the first fieldplate gate includes a first portion extending into a first recess defined in the AlGaN layer and the second fieldplate gate includes a second portion extending into a second recess defined in the AlGaN layer.

11. A structure for an III-V integrated circuit, comprising:
a depletion mode high electron mobility transistor (DM HEMT) having a first source, a first drain and a first fieldplate gate between the first source and the first drain; and
an enhancement mode HEMT (EM HEMT) having a second source and a second drain, and the EM HEMT having a gallium nitride (GaN) gate and a second fieldplate gate between the second source and the second drain, wherein the second fieldplate gate is closer to the second drain than the GaN gate.

12. The structure of claim 11, wherein the first and second fieldplate gates have a same composition, the composition being different than a composition of the GaN gate.

13. The structure of claim 11, further comprising a first interconnect coupling the second fieldplate gate and the second source.

14. The structure of claim 11, wherein each fieldplate gate includes a step.

15. The structure of claim 11, wherein the GaN gate includes a p-type GaN (pGaN) layer underneath a metallic layer.

16. The structure of claim 15, wherein the pGaN layer is in direct contact with the metallic layer.

17. The structure of claim 10, wherein each HEMT includes a passivation layer over an aluminum gallium nitride (AlGaN) layer, and wherein the first fieldplate gate includes a first portion extending into a first recess defined in the AlGaN layer and the second fieldplate gate includes a second portion extending into a second recess defined in the AlGaN layer.

18. A method, comprising:
forming a p-type gallium nitride (pGaN) gate in an enhancement mode high electron mobility transistor (EM HEMT) region over an aluminum gallium nitride (AlGaN) layer over a gallium nitride (GaN) layer over a substrate;
forming a passivation layer over the pGaN gate in the EM HEMT region and a depletion mode high electron mobility transistor (DM HEMT) region over the AlGaN layer and the GaN layer;
forming a first fieldplate gate over the passivation layer and adjacent the pGaN gate in the EM HEMT region and a second fieldplate gate over the passivation layer in the DM HEMT region;
forming a first source and a first drain on opposing sides of the first fieldplate gate; and
forming a second source and a second drain on opposing sides the pGaN gate and the second fieldplate gate, the second fieldplate gate closer to the second drain than the pGaN gate,
wherein each fieldplate gate includes a step.

19. The method of claim 18, wherein the first and second fieldplate gates have a same composition, the composition being different than a composition of the pGaN gate.

20. The method of claim 18, wherein the first fieldplate gate includes a first portion extending into a first recess defined in the passivation layer and the AlGaN layer, and the second fieldplate gate includes a second portion extending into a second recess defined in the passivation layer and the AlGaN layer.
